(19) United States
(12) Patent Application Publication
(10) Pub. No.: US 2013/0167703 A1
(43) Pub. Date: Jul. 4, 2013

(54) TAG HOLDER AND WORKPIECE USING THE SAME

(71) Applicants: HSIN-PEI CHANG, Tu-Cheng (TW); ZONG-YUAN SUN, Tu-Cheng (TW); DA-HUA XIAO, Shenzhen City (CN)

(72) Inventors: HSIN-PEI CHANG, Tu-Cheng (TW); ZONG-YUAN SUN, Tu-Cheng (TW); DA-HUA XIAO, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD ., Shenzhen City (CN)

(21) Appl. No.: 13/558,478

(22) Filed: Jul. 26, 2012

(30) Foreign Application Priority Data
Dec. 29, 2011 (CN) 201110450665.9

(51) Int. Cl. H05K 7/00; B26D 1/00

(52) U.S. Cl. 83/698.11; 248/309.1; 248/315

(57) ABSTRACT

A tag holder includes a top surface, a bottom surface opposite to the top surface, an inner surface, and an outer surface. The outer surface and the inner surface connect to the top surface and the bottom surface. The top surface defines at least one receiving cavity. The inner surface defines at least one groove. RFID tags are held by the tag holder in such a way as to provide ease of reading the tags, and to reduce any electromagnetic interference offered by the object to which the tag holder is attached.

### BACKGROUND

1. Technical Field

The disclosure generally relates to tag holders, and particularly to a radio frequency identification (RFID) tag holder.

2. Description of Related Art

RFID technology is used to track articles, such as workpieces in a factory. RFID system usually includes RFID tags and a RFID reader. The RFID tag includes an integrated circuit (IC) microchip and antenna. The microchip stores information of the workpiece and exchanges the information with RFID reader via the antenna.

When the RFID tag attached to the workpiece communicates with the RFID reader, the communication can be interfered by the workpiece. The RFID reader may not be able to identify or read the RFID tag, especially when the workpiece is made of metal. To prevent the workpiece affecting the RFID tag and reduce the interference, foam is used to wrap outside the RFID tag layer by layer and then bind the RFID tag to the metal workpiece. However, the process to wrap the RFID tag is time-consuming In addition, the attachment between the RFID tag and the workpiece is weak; the RFID tag may disengage from the workpiece during operations on the workpiece.

Therefore, there is room for improvement within the art.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the disclosure.

FIG. 1 is a schematic view of a tag holder, according to an exemplary embodiment of the disclosure.

FIG. 2 is a schematic view of a workpiece to which the tag holder of FIG. 1 is attached, according to an exemplary embodiment of the disclosure.

### DETAILED DESCRIPTION

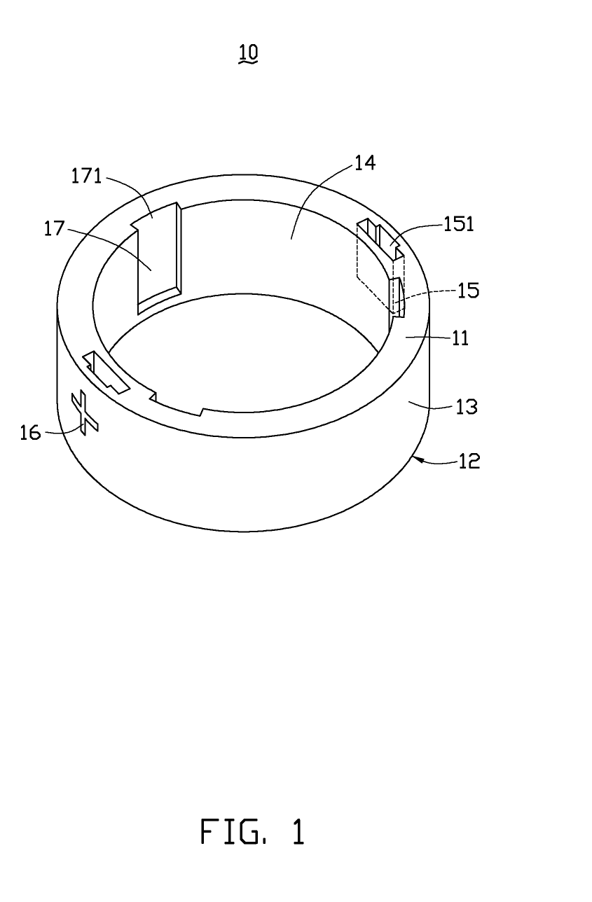

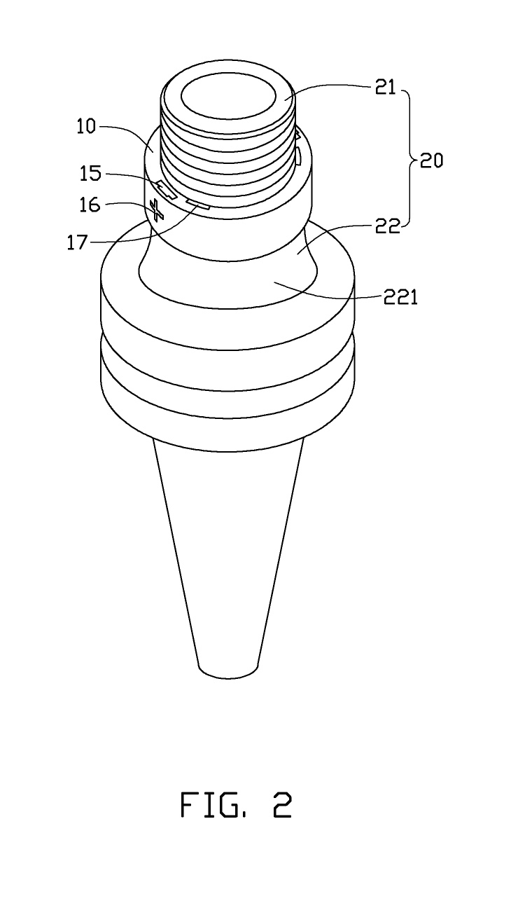

FIG. 1 is a schematic view of a tag holder 10, according to an exemplary embodiment of the disclosure. The tag holder 10 is used to hold RFID tags corresponding to a workpiece 20 (shown in FIG. 2). The tag holder 10 can be attached to the workpiece 20 with the RFID tags received therein. Thus, the workpiece 20 can be identified and tracked via the RFID tags.

Referring to FIG. 2, in this embodiment, the workpiece 20 is a cutting tool including a cylindrical shaft portion 21 and a cutting portion 22 formed on an end of the shaft portion 21. The cutting portion 22 can be rotated together with the shaft portion 21 for machining an accessory. An arc-shaped mounting surface 221 is formed on the cutting portion 21 adjacent to the shaft portion 21 to match the tag holder 10.

The tag holder 10 is made of polyoxymethylene (POM). The tag holder 10 is substantially annular and includes a top surface 11, a bottom surface 12 opposite to the top surface 11, an outer surface 13 and an inner surface 14. The top surface 11 and the bottom surface 12 are annular. The outer surface 13 and the inner surface 14 are curved surfaces connecting to the top surface 11 and the bottom surface 12. The tag holder 10 can be sleeved around the workpiece 20 with the inner surface 14 being attached to the mounting surface 221. When a shape of the workpiece 20 is changed, a shape of the tag holder 10 can be adjusted to adapt to the workpiece 20.

A plurality of receiving cavities 15 are defined in the top surface 11 extending towards the bottom surface 12 and formed between the outer surface 13 and the inner surface 14. An opening 151 on the top surface 11 forms the mouth of each receiving cavity 15. The RFID tags can be inserted into the receiving cavities 15 via the opening 151. A shape and size of each receiving cavity 15 correspond to those of the RFID tags. In this embodiment, a cross section of the receiving cavities 15 is substantially T-shaped, and the top surface 11 defines two diametrically-opposed receiving cavities 15. The two receiving cavities 15 can each receive one RFID tag. Thus, during a rotating process of the workpiece 20, when one of the RFID tags is rotated beyond an effective identifying range of an RFID reader, the other one of the RFID tags will be rotated within the effective identifying range of an RFID reader and can be identified by the RFID reader.

In addition, the exact position of each receiving cavity 15 can be marked or indicated by means of a symbol 16 formed and visible on the outer surface of the tag holder 10. In this embodiment, the symbols 16 are cross-shaped characters.

A plurality of grooves 17 are defined in the inner surface 14 along a horizontal direction for injecting glue. A cut 171 is formed on the top surface 171 corresponding to each of the grooves 17. When the tag holder 10 is sleeved around the cutting tool 20 with the inner surface 14 in contact with the mounting surface 221, the glue can be injected into the grooves 17 via the cuts 171. Thus, the tag holder 10 is securely attached to the cutting tool 20 and will not easily be disengaged from the cutting tool 20 during operations on or by the cutting tool 20. In this embodiment, the number of the grooves 17 is three. The three grooves 17 are equidistantly positioned around the inner surface 14.

In use, each tag holder 10 has two RFID tags, respectively received in each of the receiving cavities 15. To fix the RFID tags in the receiving cavities 15, glue or adhesive tape can be used to adhere the RFID tags within the receiving cavities 15. The tag holder 10 is sleeved around the cutting tool 20 along the shaft portion 21 toward the cutting portion 22. The inner surface 14 tightly contacts the mounting surface 22 with the top surface 11 facing the shaft portion 21. The glue is injected into the grooves 17 via the cuts 171 to further affix the tag holder 10 to the cutting tool 20.

Therefore, the cutting tool 20 can be identified and tracked by the RFID tags. In addition, the physical isolation or insulation of the RFID tags from the workpiece 20 reduces interference by the workpiece 20.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A tag holder, comprising:
a top surface;
a bottom surface opposite to the top surface;
an inner surface; and
an outer surface, the outer surface and the inner surface connecting to the top surface and the bottom surface; wherein the top surface defines at least one receiving cavity, and the inner surface defines at least one groove.

2. The tag holder of claim 1, wherein the tag holder is annular.

3. The tag holder of claim 1, wherein the top surface defines the at least one receiving cavity extending toward the bottom surface, the at least one receiving cavity is positioned between the inner surface and the outer surface, and forming a corresponding opening in the top surface.

4. The tag holder of claim 1, wherein the outer surface defines a symbol corresponding to the position of the at least one receiving cavity.

5. The tag holder of claim 1, wherein the at least one groove forms a corresponding cut in the top surface.

6. The tag holder of claim 1, wherein the top surface defines two receiving cavities symmetrically positioned on the top surface.

7. The tag holder of claim 1, wherein the inner surface defines three grooves, the three grooves are equidistantly positioned around the inner surface.

8. A workpiece, comprising:
a shaft portion;
a cutting portion positioned at one end of the shaft portion, the cutting portion comprising a mounting surface; and
a tag holder sleeved around the cutting portion, the tag holder comprising:
a top surface;
a bottom surface opposite to the top surface;
an inner surface attached to the mounting surface with the inner surface in contact with the mounting surface; and
an outer surface, the outer surface and the inner surface connecting to the top surface and the bottom surface; wherein the top surface defines at least one receiving cavity, the inner surface defines at least one groove.

9. The workpiece of claim 8, wherein the tag holder is annular.

10. The workpiece of claim 8, wherein the workpiece is a cutting tool.

11. The workpiece of claim 8, wherein glue is injected into the at least one groove to securely fix the inner surface to the mounting surface.

12. The workpiece of claim 8, wherein the at least one receiving cavity is configured for receiving RFID tags, when the RFID tag is received in the at least one receiving cavity, a distance is formed between the RFID tag and the workpiece.

13. The workpiece of claim 8, wherein the top surface defines the at least one receiving cavity extending toward the bottom surface, the at least one receiving cavity is positioned between the inner surface and the outer surface, and forming a corresponding opening in the top surface.

14. The workpiece of claim 8, wherein the outer surface defines a symbol corresponding to the position of the at least one receiving cavity.

15. The workpiece of claim 8, wherein the at least one groove forms a corresponding cut in the top surface.

16. The workpiece of claim 8, wherein the top surface defines two receiving cavities symmetrically positioned on the top surface.
